(19) United States
(12) Patent Application Publication
(10) Pub. No.: US 2014/0103480 A1
(43) Pub. Date: Apr. 17, 2014

(54) Mask, TFT Glass Substrate and the Manufacturing Method Thereof

(71) Applicants: Pei Lin, Guangdong (CN); Hua Zheng, Shenzhen City (CN); Liangdong Wu, Shenzhen City (CN); Shangpan Chen, Shenzhen City (CN); Long Pan, Shenzhen City (CN); Pan Gao, Shenzhen City (CN); Mingwen Lin, Shenzhen City (CN); Shyh-Feng Chen, Shenzhen City (CN)

(72) Inventors: Pei Lin, Guangdong (CN); Hua Zheng, Shenzhen City (CN); Liangdong Wu, Shenzhen City (CN); Shangpan Chen, Shenzhen City (CN); Long Pan, Shenzhen City (CN); Pan Gao, Shenzhen City (CN); Mingwen Lin, Shenzhen City (CN); Shyh-Feng Chen, Shenzhen City (CN)

(73) Assignee: SHENZHEN CHINA STAR OPTOELECTRONICS TECHNOLOGY CO, GUANGDONG (CN)

(21) Appl. No.: 13/643,530

(22) PCT Filed: Oct. 19, 2012
(86) PCT No.: PCT/CN12/83202

§ 371 Date: Oct. 25, 2012

(30) Foreign Application Priority Data
Oct. 17, 2012 (CN) 201210395055.8

(51) Int. Cl. H01L 31/18; G03F 1/00; H01L 27/144

(52) U.S. Cl. CPC H01L 31/18; H01L 27/144; G03F 1/00
USPC 257/466; 438/68; 430/5; 257/E27.127; 257/E31.052

(57) ABSTRACT

A mask for partially blocking ultraviolet rays in TFT glass substrate manufacturing process is disclosed. The mask includes a panel pattern area for forming the panel patterns, and an additional pattern area for forming additional patterns in a rim of the panel pattern area. In addition, a TFT glass substrate and the manufacturing thereof are also disclosed. By arranging the additional patterns in the rim of the panel patterns, the microstructures in the rim of the panel patterns are substantially the same with that in the middle of the panel patterns.

### BACKGROUND OF THE INVENTION

1. Field of the Invention

Embodiments of the present disclosure relate to display technology, and more particularly to a mask, a TFT glass substrate and the manufacturing method thereof.

2. Discussion of the Related Art

In order to obtain better display performance, line distances of pixel electrodes are decreased in accordance with the larger dimension of liquid crystal panels. For example, the line distance of the pixel electrode is reduced from 5-8 um to 3 um, which is restricted by etching, coating, or developing processes. Thus, one key issue is to further reduce the line distance to be 2.5 um, or even to be 2 um.

Currently, there is a great difference between the line distance of a rim area of panel patterns and that of a middle area of the panel patterns while the line distances are reduced to be 2.5 um. However, the line distances of the rim area and the middle area cannot be uniformed due to the above-mentioned restrictions.

FIG. 1 is a schematic view of a conventional TFT glass substrate. The TFT glass substrate 10 includes a plurality of panel patterns 11 and a blank area 12. The panel patterns 11 are spaced apart from each other. In conventional technology, all of the photo resistors on the blank area 12 are exposed to ultraviolet rays, and are dissolved due to a developing procedure.

When the TFT glass substrate 10 reacts with the exposed photo resistors, more photo resistors in the blank area 12 have to react with a developing solution than that in the rim of the panel patterns 11. As such, the concentration of the developing solution in the blank area 12 is greatly decreased. Further, the developing effect in the rim of the panel patterns 11 is not enough so that the line distances of the pixel electrodes are small.

FIG. 2 is a schematic view of the line distance of the TFT glass substrate of FIG. 1. The X-axis indicates the measuring locations, and the Y-axis indicates values of line distances. The line distances of the pixel electrodes in the rim of the panel patterns 11 are highlighted by the circle. It can be seen that the line distances of the pixel electrodes in the rim of the panel patterns 11 is small.

### SUMMARY

The object of the claimed invention is to provide a mask, a TFT glass substrate and the manufacturing method thereof.

In one aspect, a mask for partially blocking ultraviolet rays in TFT glass substrate manufacturing process includes a panel pattern area for forming the panel patterns, and an additional pattern area for forming additional patterns in a rim of the panel pattern area.

Wherein the panel patterns include panel microstructures, and the additional patterns include additional microstructures.

Wherein the panel microstructures and the additional microstructures are substantially the same.

Wherein the additional microstructures are extensions of the panel microstructures.

Wherein the additional patterns are rectangular-shaped, saw-shaped, or ripple-shaped.

In another aspect, a manufacturing method of TFT glass substrate includes: washing the glass substrate; depositing a thin film on the glass substrate; coating the glass substrate with photo resistors; exposing the glass substrate to ultraviolet rays so as to form panel patterns and to form additional patterns in a rim of the panel patterns; applying a developing procedure to the glass substrate; etching the glass substrate; stripping the glass substrate; and cutting the glass substrate to form the TFT glass substrate.

Wherein the panel patterns include panel microstructures, and the additional patterns include additional microstructures.

Wherein the panel microstructures and the additional microstructures are substantially the same.

Wherein the additional microstructures are extensions of the panel microstructures.

Wherein the additional patterns are rectangular-shaped, saw-shaped, or ripple-shaped.

In another aspect, a TFT glass substrate includes panel patterns, additional patterns arranged in a rim of the panel patterns, and wherein only portions of the additional patterns are exposed to ultraviolet rays so that an amount of photo resistors involving with a developing procedure is decreased.

Wherein the panel patterns include panel microstructures, and the additional patterns include additional microstructures.

Wherein the panel microstructures and the additional microstructures are the same.

Wherein the additional microstructures are extensions of the panel microstructures.

Wherein the additional patterns are rectangular-shaped, saw-shaped, or ripple-shaped.

By arranging additional patterns in the rim of the panel patterns, an amount of the photo resistors involving with the developing procedure is decreased. In this way, the microstructures in the rim of the panel patterns are substantially the same with that in the middle of the panel patterns. Thus, the line distances of the pixel electrode in the rim of the panel pattern are reduced.

### BRIEF DESCRIPTION OF THE DRAWINGS

FIG. 1 is a schematic view of a conventional TFT glass substrate.

FIG. 2 is a schematic view of the line distances of the TFT glass substrate of FIG. 1.

FIG. 3 is a schematic view of a pixel electrode of one vertical alignment mode.

FIG. 4 is a schematic view of the mask in accordance with one embodiment.

FIG. 5 is a flowchart of the manufacturing method of the TFT glass substrate in accordance with one embodiment.

FIG. 6 is a schematic view of TFT glass substrate in accordance with one embodiment.

FIG. 7 is a schematic view of the line width of the TFT glass substrate of FIG. 6.

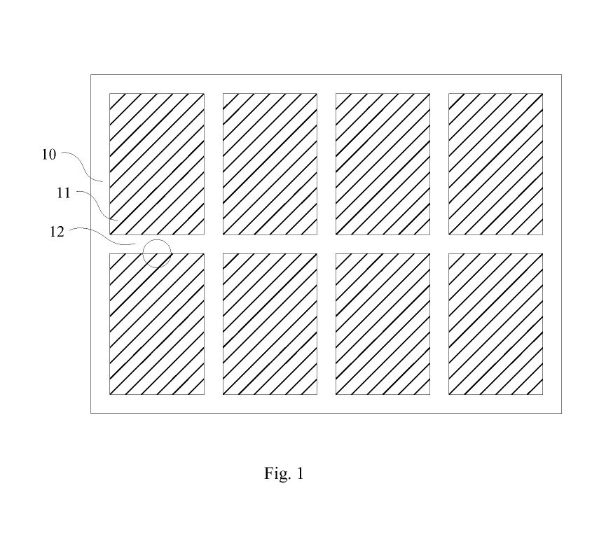

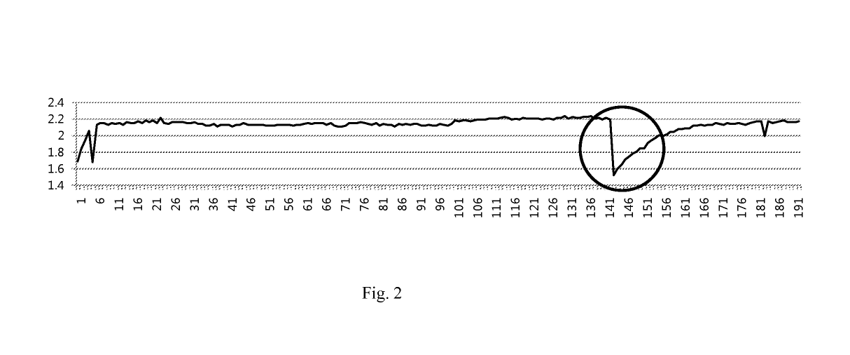

### DETAILED DESCRIPTION OF THE EMBODIMENTS

Embodiments of the invention will now be described more fully hereinafter with reference to the accompanying drawings, in which embodiments of the invention are shown.

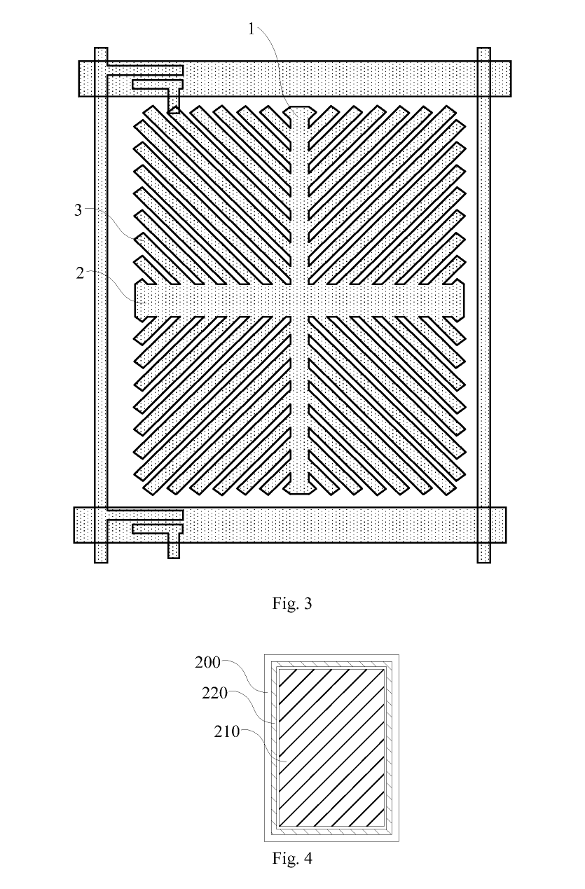

FIG. 3 is a schematic view of a pixel electrode of one vertical alignment mode. The electrode pixel includes a vertical main trunk 1, a horizontal main trunk 2, and a plurality of slits 3. The vertical main trunk 1, the horizontal main trunk 2, and the slits 3 are bar-shaped, and the slits 3 are arranged at an angle to the vertical main trunk 1 and the horizontal main trunk 2. A width of the slits 3 is referred to as “line width” and a distance between the slits 3 is referred to as “line distance” of the pixel electrode.

Conventionally, a great deal of photo resistors in the blank area 12 reacts with a great deal of developers in an exposure procedure. As such, the developers are not enough in the rim so that the line width is narrow. The differences between the line distances in the rim of the panel patterns and the line distances in the middle of the panel patterns are large, and thus the defective rate is high.

FIG. 4 is a schematic view of a mask 200 in accordance with one embodiment. The mask 200 is for blocking ultraviolet rays during the exposure procedure of TFT glass substrate manufacturing. The mask 200 includes a panel pattern area 210 and an additional pattern area 220.

The panel pattern area 210 is for forming the panel patterns. The additional pattern area 220 is arranged in a rim of the panel pattern area 210 for forming additional patterns.

Specifically, the panel patterns include panel microstructures, and the additional patterns include additional microstructures. The microstructures are shown in FIG. 3, and the line distance of the pixel electrodes is of 2.5 um or 2 um.

In the embodiment, the panel microstructures and the additional microstructures may be the same. For example, the panel microstructures may include a plurality of bar-shaped branches, and the additional microstructures may also include a plurality of bar-shaped branches. In addition, the line distance of the panel microstructures may be substantially the same with that of the additional microstructures.

In one embodiment, the additional microstructures may be extensions of the panel microstructures. That is, the mask 200 may form an enlarged pattern. As the large differences between the line distances within the panel patterns is mainly caused by the line distances in the rim of the blank areas, and thus a standard pattern may be obtained by cutting the rim of the enlarged pattern.

In other embodiments, there are no microstructures in the additional patterns. The additional patterns are only for blocking portions of the blank area in the exposure procedure so that an amount of the photo resistors involving with the developing procedure is decreased. It is proved by experiments that the differences of the line distances are reduced by arranging the additional patterns in the blank area. It is understood that the additional patterns may be rectangular-shaped, saw-shaped, or ripple-shaped.

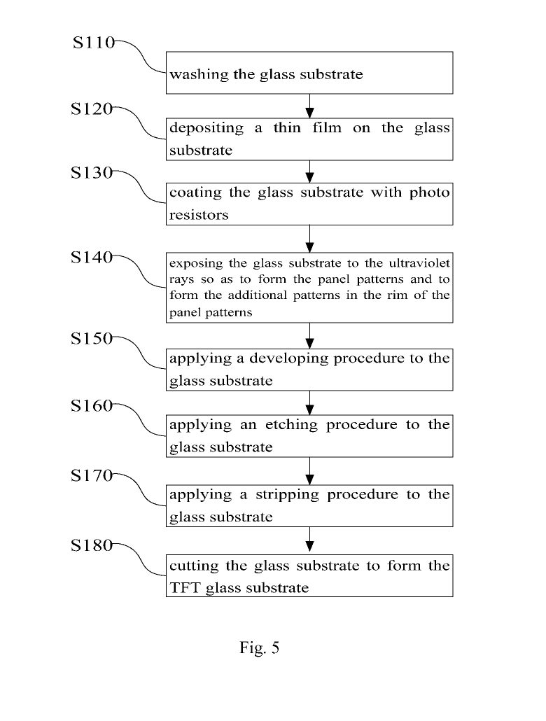

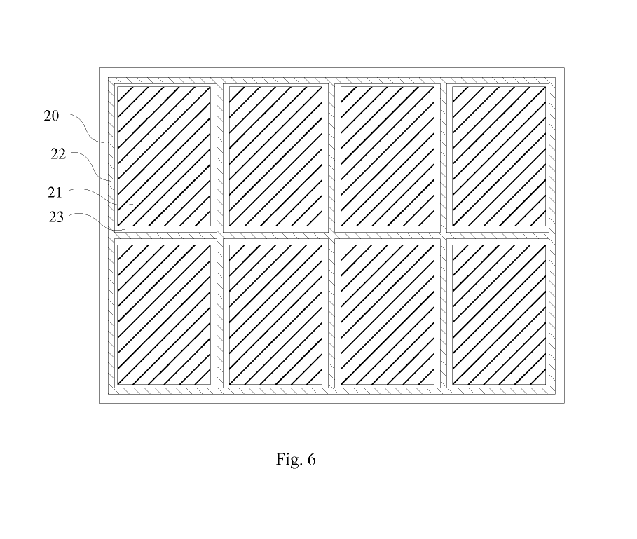

FIG. 5 is a flowchart of the manufacturing method of the TFT glass substrate in accordance with one embodiment. The manufacturing method includes the following steps.

In step S110, a washing procedure is applied to the glass substrate.

In step S120, the glass substrate is deposited with a thin film.

In step S130, the glass substrate is coated with photo resistors.

In step S140, the glass substrate is exposed to the ultraviolet rays so as to form the panel patterns and to form the additional patterns in the rim of the panel patterns.

In step S150, a developing procedure is applied to the glass substrate.

In step S160, an etching procedure is applied to the glass substrate.

In step S170, a stripping procedure is applied to the glass substrate.

In step S180, the glass substrate is cut to form the TFT glass substrate.

Specifically, the manufacturing method adopts the mask 200 in the exposure procedure so as to form the panel pattern and the additional pattern as shown in FIG. 6.

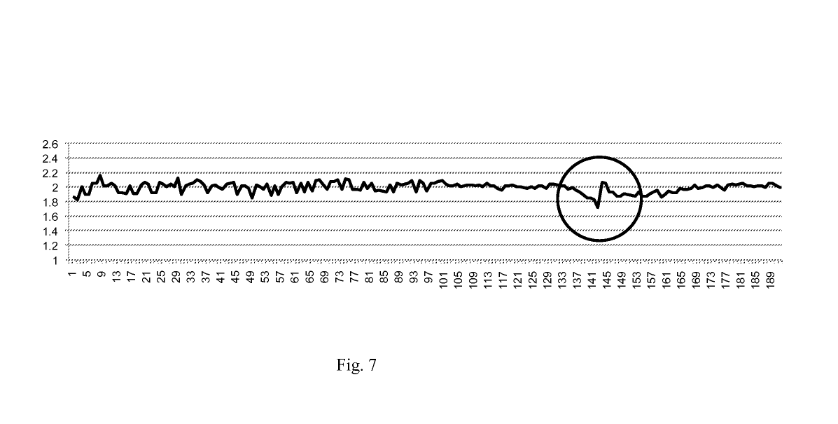

By adopting the mask 200 in the exposure procedure, only portions of the blank area 23 is exposed to the ultraviolet rays so that the amount of the photo resistors involving with the developing procedure is decreased. It is proved by experiments that the differences of the line distances within the panel patterns are reduced by arranging the additional patterns in the blank area 23. As shown in FIG. 7, the difference of the line distance within the panel patterns is improved to be 0.2 um after adopting the additional pattern, and that of the conventional technology is 0.6 um. It is understood that the additional patterns may be rectangular-shaped, saw-shaped, or ripple-shaped.

By adopting the above manufacturing method, the TFT glass substrate 20 of FIG. 6 may be obtained by executing steps S110 to S140. The TFT glass substrate 20 includes panel patterns 21 and additional patterns 22. The additional patterns 22 are in the rim of the panel patterns 21. In addition, only portions of the additional patterns 22 are exposed to the ultraviolet rays so that the amount of the photo resistors involving with the developing procedure, which are located in the rim of the panel pattern 21, is decreased. The panel patterns 21 include panel microstructures, and the additional patterns 22 include additional microstructures. The microstructures are shown in FIG. 3.

In the embodiment, the panel microstructures and the additional microstructures may be the same. For example, the panel microstructures may include a plurality of bar-shaped branches, and the additional microstructures may also include a plurality or bar-shaped branches. In addition, the line distances of the panel microstructures may be substantially the same with that of the additional microstructures.

In one embodiment, the additional microstructures may be an extension of the panel microstructures. That is, the mask 200 may form an enlarged pattern. As the differences of the line distances within the panel patterns is mainly caused by the line distances in the rim of the blank areas, and thus a standard pattern may be obtained by cutting the edges of the enlarged pattern.

In other embodiments, there are no microstructures in the additional pattern. The additional pattern is only for blocking portions of the blank area in the exposure procedure so that the amount of the photo resistors involving with the developing procedure is decreased.

In view of the above, the amount of the photo resistors involving in the developing procedure is decreased by arranging the additional patterns in the rim of the panel patterns. In this way, the microstructures in the rim of the panel patterns are substantially the same with that in the middle of the panel patterns. Thus, the line distances of the pixel electrode in the rim of the panel pattern are reduced.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A mask for partially blocking ultraviolet rays in TFT glass substrate manufacturing process, comprising:
a panel pattern area for forming the panel patterns; and
an additional pattern area for forming additional patterns in a rim of the panel pattern area.

2. The mask as claimed in claim 1, wherein the panel patterns comprise panel microstructures, and the additional patterns comprise additional microstructures.

3. The mask as claimed in claim 2, wherein the panel microstructures and the additional microstructures are substantially the same.

4. The mask as claimed in claim 2, wherein the additional microstructures are extensions of the panel microstructures.

5. The mask as claimed in claim 1, wherein the additional patterns are rectangular-shaped, saw-shaped, or ripple-shaped.

6. A manufacturing method of TFT glass substrate, comprising:
washing the glass substrate;
depositing a thin film on the glass substrate;
coating the glass substrate with photo resistors;
exposing the glass substrate to ultraviolet rays so as to form panel patterns and to form additional patterns in a rim of the panel patterns;
applying a developing procedure to the glass substrate;
etching the glass substrate;
stripping the glass substrate; and
cutting the glass substrate so as to form the TFT glass substrate.

7. The manufacturing method as claimed in claim 6, wherein the panel patterns comprise panel microstructures, and the additional patterns comprise additional microstructures.

8. The manufacturing method as claimed in claim 7, wherein the panel microstructures and the additional microstructures are substantially the same.

9. The manufacturing method as claimed in claim 7, wherein the additional microstructures are extensions of the panel microstructures.

10. The manufacturing method as claimed in claim 6, wherein the additional patterns are rectangular-shaped, saw-shaped, or ripple-shaped.

11. A TFT glass substrate, comprising:
panel patterns;
additional patterns arranged in a rim of the panel patterns; and
wherein only portions of the additional patterns are exposed to ultraviolet rays so that an amount of photo resistors involving with a developing procedure is decreased.

12. The TFT glass substrate as claimed in 11, wherein the panel patterns comprise panel microstructures, and the additional patterns comprise additional microstructures.

13. The TFT glass substrate as claimed in 12, wherein the panel microstructures and the additional microstructures are the same.

14. The TFT glass substrate as claimed in 14, wherein the additional microstructures are extensions of the panel microstructures.

15. The TFT glass substrate as claimed in 12, wherein the additional patterns are rectangular-shaped, saw-shaped, or ripple-shaped.
